(19) United States
(12) Patent Application Publication
(10) Pub. No.: US 2026/0276326 A1
(43) Pub. Date: Sep. 17, 2026

(54) ALUMINUM HYDROCARBON COATED PINS PLATE

(71) Applicant: FAIZAN AHMED, SAN JOSE, CA (US)

(72) Inventor: FAIZAN AHMED, SAN JOSE, CA (US)

(21) Appl. No.: 19/412,844

(22) Filed: Dec. 8, 2025

Related U.S. Application Data
(60) Provisional application No. 63/770,766, filed on Mar. 12, 2025.

(51) Int. Cl. F28F 13/18; F28D 21/00; H10N 10/13

(52) U.S. Cl. CPC F28F 13/18; F28D 21/00; H10N 10/13; F28D 2021/0029

(57) ABSTRACT

In one aspect, a thermally conductive interface structure comprises an aluminum substrate, a plurality of pins formed integrally with the aluminum substrate, and a hydrocarbon coating disposed on the aluminum substrate and on the plurality of pins. The hydrocarbon coating is deposited through a controlled polymerization process to form a continuous conductive layer that conforms to curved pin surfaces and planar substrate surfaces. The plurality of pins are arranged in a predetermined pattern on the aluminum substrate to define a high surface area conductive array. The aluminum substrate and the plurality of pins are configured to receive thermal energy from a thermoelectric semiconductor device along an oblique heat flow path established by a non perpendicular mounting orientation of the thermoelectric semiconductor device relative to a cooled payload chamber and to redistribute the received thermal energy laterally across the aluminum substrate and axially along the plurality of pins to enhance thermal spreading and increase heat rejection efficiency.

### BACKGROUND

### Field of the Invention

The present invention relates generally to portable temperature-controlled storage systems, and more particularly to an aluminum hydrocarbon coated pins plate.

### Background

Temperature-sensitive materials, particularly in medical and biological applications, require precise temperature control during storage and transport. Traditional cooling systems rely on compressors, refrigerants, or ice packs that are bulky, inefficient, and unable to maintain consistent temperatures. Current portable cooling solutions face significant challenges in maintaining precise temperatures while operating on battery power.

The limitations of existing portable cooling systems are particularly evident in applications requiring extended autonomous temperature control. Traditional compressor-based systems consume significant power and are impractical for portable use, while passive cooling solutions using ice packs or phase change materials cannot maintain precise temperature control over long periods.

Additionally, existing systems often suffer from inefficient heat transfer between cooling elements and payload chambers, leading to temperature gradients and inconsistent cooling. This technical challenge is particularly acute in compact portable systems where space constraints limit traditional heat transfer approaches.

### BRIEF SUMMARY OF THE INVENTION

In one aspect, a thermally conductive interface structure comprises an aluminum substrate, a plurality of pins formed integrally with the aluminum substrate, and a hydrocarbon coating disposed on the aluminum substrate and on the plurality of pins. The hydrocarbon coating is deposited through a controlled polymerization process to produce a continuous conductive layer that conforms to curved pin surfaces and planar substrate surfaces. The plurality of pins are arranged in a predetermined pattern on the aluminum substrate to define a high surface area conductive array. The aluminum substrate and the plurality of pins are configured to receive thermal energy from a thermoelectric semiconductor device along an oblique heat flow path established by a non-perpendicular mounting orientation of the thermoelectric semiconductor device relative to a cooled payload chamber and to redistribute the received thermal energy laterally across the aluminum substrate and axially along the plurality of pins to enhance thermal spreading and increase heat rejection efficiency.

In another aspect, a thermally managed refrigeration interface system comprising: an aluminum payload chamber defining an interior cooled volume and comprising a hydrocarbon coated chamber wall forming a cold side thermal interface region; a thermoelectric semiconductor device mounted adjacent to the hydrocarbon coated chamber wall such that a cold side of the thermoelectric semiconductor device is in direct thermal communication with the hydrocarbon coated chamber wall and a hot side of the thermoelectric semiconductor device is oriented away from the payload chamber; an aluminum pin plate assembly positioned in direct thermal contact with the hot side of the thermoelectric semiconductor device, the aluminum pin plate assembly comprising an aluminum base plate and a plurality of pins formed integrally with the aluminum base plate, each pin extending into a downstream heat rejection region; a hydrocarbon composite coating disposed on the aluminum base plate and on the plurality of pins, the hydrocarbon composite coating being formed by thermally polymerizing a blended mixture of tetradecane and a polymer material to produce a wax like solid coating that continuously conforms to curved pin surfaces and planar base plate surfaces; wherein the plurality of pins are arranged in a predetermined high density array comprising approximately one hundred and twenty pins arranged at a center to center pitch of approximately 8.07 millimeters with each pin having a diameter of approximately five millimeters and a nominal height in a range from approximately thirty millimeters to approximately fifty millimeters; wherein the aluminum base plate is manufactured with a hole diameter tolerance of plus or minus 0.025 millimeters, a hole position tolerance of plus or minus 0.05 millimeters, a wall thickness tolerance of plus or minus 0.05 millimeters, and an outer dimension tolerance of plus or minus 0.1 millimeters, and further comprises standard M5 by 0.8 threaded mounting features configured to maintain controlled contact pressure against the hot side of the thermoelectric semiconductor device using mechanical fasteners; wherein the thermoelectric semiconductor device is mounted at a non perpendicular angle relative to the hydrocarbon coated chamber wall such that thermal energy enters the aluminum base plate of the aluminum pin plate assembly along an oblique heat flow path; and wherein thermal energy propagated from the payload chamber through the thermoelectric semiconductor device is redistributed laterally across the aluminum base plate and axially along the plurality of pins into a forced air or liquid cooled heat rejection region, thereby establishing bidirectional thermal conduction capability for operation in both cooling and heating modes while preventing thermal saturation of the thermoelectric semiconductor device during extended autonomous operation.

### BRIEF DESCRIPTION OF THE DRAWINGS

FIG. 1 is a top view of example embodiment of a portable temperature-controlled enclosure, according to some embodiments.

FIGS. 2 and 3 are isometric views of example embodiment of a portable temperature-controlled enclosure, according to some embodiments.

FIG. 4 is a front view of example embodiment of a portable temperature-controlled enclosure, according to some embodiments.

FIG. 5 is a side view of example embodiment of a portable temperature-controlled enclosure, according to some embodiments.

FIG. 6-9 illustrate various example views of an aluminum cooling chamber portable unit, according to some embodiments.

FIG. 6 illustrates a top-view of aluminum cooling chamber portable unit, according to some embodiments.

FIG. 7 illustrates a isometric-view of aluminum cooling chamber portable unit, according to some embodiments.

FIG. 8 illustrates a rear-view of aluminum cooling chamber portable unit, according to some embodiments.

FIG. 9 illustrates a side-view of aluminum cooling chamber portable unit, according to some embodiments.

FIG. 10 is a block diagram of a sample computing environment that can be utilized to implement various embodiments.

FIG. 11 illustrates a logical view of a portable temperature-controlled enclosure, according to some embodiments.

FIG. 12 illustrates an aluminum hydrocarbon coated pin plate assembly according to some embodiments.

FIG. 13 illustrates the aluminum hydrocarbon coated pin plate assembly in another representative orientation according to some embodiments.

The Figures described above are a representative set and are not an exhaustive with respect to embodying the invention.

### DESCRIPTION

Disclosed are a system, method, and article of manufacture for an Aluminum Hydrocarbon Coated Pins Plate. The following description is presented to enable a person of ordinary skill in the art to make and use the various embodiments. Descriptions of specific devices, techniques, and applications are provided only as examples. Various modifications to the examples described herein can be readily apparent to those of ordinary skill in the art, and the general principles defined herein may be applied to other examples and applications without departing from the spirit and scope of the various embodiments.

Reference throughout this specification to ‘one embodiment,’ ‘an embodiment,’ ‘one example,’ or similar language means that a particular feature, structure, or characteristic described in connection with the embodiment is included in at least one embodiment, according to some embodiments. Thus, appearances of the phrases ‘in one embodiment,’ ‘in an embodiment,’ and similar language throughout this specification may, but do not necessarily, all refer to the same embodiment.

Furthermore, the described features, structures, or characteristics of the invention may be combined in any suitable manner in one or more embodiments. In the following description, numerous specific details are provided, such as examples of programming, software modules, user selections, network transactions, database queries, database structures, hardware modules, hardware circuits, hardware chips, etc., to provide a thorough understanding of embodiments of the invention. One skilled in the relevant art can recognize, however, that the invention may be practiced without one or more of the specific details, or with other methods, components, materials, and so forth. In other instances, well-known structures, materials, or operations are not shown or described in detail to avoid obscuring aspects of the invention.

The schematic flow chart diagrams included herein are generally set forth as logical flow chart diagrams. As such, the depicted order and labeled steps are indicative of one embodiment of the presented method. Other steps and methods may be conceived that are equivalent in function, logic, or effect to one or more steps, or portions thereof, of the illustrated method. Additionally, the format and symbols employed are provided to explain the logical steps of the method and are understood not to limit the scope of the method. Although various arrow types and line types may be employed in the flow chart diagrams, and they are understood not to limit the scope of the corresponding method. Indeed, some arrows or other connectors may be used to indicate only the logical flow of the method. For instance, an arrow may indicate a waiting or monitoring period of unspecified duration between enumerated steps of the depicted method. Additionally, the order in which a particular method occurs may or may not strictly adhere to the order of the corresponding steps shown.

DEFINITIONS

Example definitions for some embodiments are now provided.

Acrylonitrile butadiene styrene (ABS) is a common plastic polymer.

High-density polyethylene (HDPE) or polyethylene high-density (PEHD) is a polyethylene thermoplastic made from petroleum.

Phase change material (PCM) is a substance with a high heat of fusion which, melting and solidifying at a certain temperature, is capable of storing and releasing large amounts of energy. Heat is absorbed or released when the material changes from solid to liquid and vice versa. Example PCM materials can include, inter alia: organic (paraffin and nonparaffin), inorganic (salt hydrates and metallic alloys), and eutectic (mixture of two or more PCM components: organic, inorganic, and both).

Polypropylene (PP) is a thermoplastic polymer used in a wide variety of applications. It is produced via chain-growth polymerization from the monomer propylene.

Press fit or friction fit is a fastening between two parts which is achieved by friction after the parts are pushed together, rather than by any other means of fastening.

Temperature sensors can include mechanical temperature sensors, electrical temperature sensors, integrated circuit sensors, medometers, etc.

Thermoelectric effect is the direct conversion of temperature differences to electric voltage and vice versa via a thermocouple. A thermoelectric device creates voltage when there is a different temperature on each side. Conversely, when a voltage is applied to it, heat is transferred from one side to the other, creating a temperature difference. At the atomic scale, an applied temperature gradient causes charge carriers in the material to diffuse from the hot side to the cold side.

Thermal control material (TCM) is a substance capable of storing and releasing thermal energy to regulate temperature. It is noted that TCM can include phase change materials (PCM) such as paraffins, salt hydrates, and eutectic mixtures, thermal mass materials such as water or glycol solutions, and other heat storage media. TCM can include: Phase change materials (PCM) that store energy through phase transitions (e.g., paraffins, salt hydrates, eutectic mixtures); Sensible heat storage materials that store energy through temperature change (e.g., water, glycol solutions, mineral oils, molten salts); Solid thermal mass materials providing thermal inertia (e.g., concrete, ceramic, stone, sand); Metallic thermal buffers with high conductivity (e.g., aluminum heat sinks, copper spreaders, graphite plates, metal foam); and Composite thermal materials combining multiple thermal management functions (e.g., metal matrix composites, polymer-PCM encapsulations, graphene-enhanced compounds).

### Example Smart Refrigerator Exterior Views

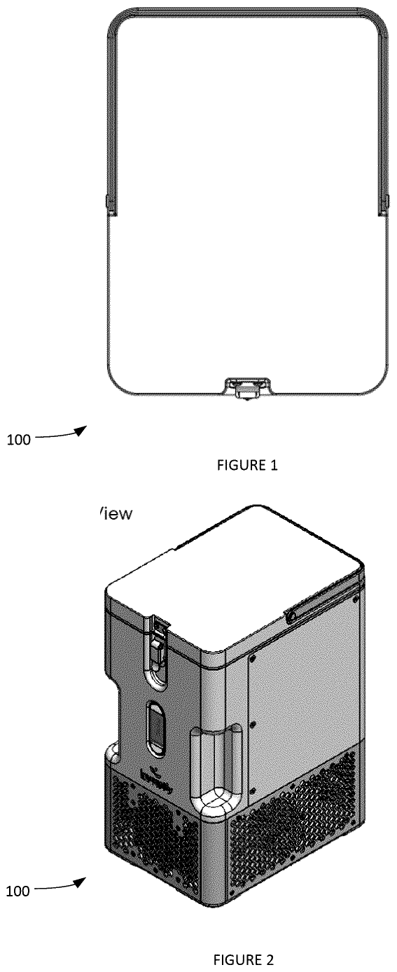

FIGS. 1-5 provide series of views of an example embodiment of a portable temperature-controlled enclosure 100, according to some embodiments. The series of views includes a set of orthographic views (e.g. top, front, side, and isometric) of the portable temperature-controlled enclosure according to one embodiment. The example embodiment of a portable temperature-controlled enclosure 100 can be a top loaded system. Portable temperature-controlled enclosure 100 can include an optimized solid-state cooling system (e.g. see infra). Portable temperature-controlled enclosure 100 provides a portable temperature-controlled enclosure utilizing an innovative solid-state cooling system with optimized thermal management. Portable temperature-controlled enclosure 100 combines advanced thermoelectric cooling technology with control systems to achieve superior temperature stability and extended battery operation.

Portable temperature-controlled enclosure 100 comprises several key components working in concert: a precision-engineered payload chamber for storing temperature-sensitive materials, an optimized thermoelectric cooling system with angular mounting configuration, an integrated TCM chamber for thermal buffering, and a heat dissipation system including honeycomb ventilation. These components are managed by advanced monitoring and control systems, all supported by extended battery-powered operation capability.

The top-loading portable temperature-controlled enclosure 100 represents a breakthrough in portable refrigeration technology, utilizing solid-state cooling principles to maintain precise temperature control. The top-loading portable temperature-controlled enclosure 100 distinguishes itself through the complete elimination of traditional cooling infrastructure components such as compressors, refrigerant gases, cooling coils, ice packs, or gel packs.

Example physical specifications of the top-loading portable temperature-controlled enclosure 100 are now discussed. The top-loading portable temperature-controlled enclosure 100 payload capacity, by way of example, can be a one (1) liter. The top-loading portable temperature-controlled enclosure 100 can include a top-loading design with example dimensions of 107.78 mm×119.92 mm×166.84 mm.

Access to the top-loading portable temperature-controlled enclosure 100 can be via a top-mounted lid providing full access to internal chamber. Construction of The top-loading portable temperature-controlled enclosure 100 can include precision-engineered aluminum chamber with integrated cooling system.

An example Core Cooling Technology of the top-loading portable temperature-controlled enclosure 100 is now discussed. The top-loading portable temperature-controlled enclosure 100 employs an advanced solid-state cooling mechanism based on semiconductor physics. As a cooling principle, the top-loading portable temperature-controlled enclosure 100 utilizes an electron mobility differential between semiconductor materials. By way of operation, the top-loading portable temperature-controlled enclosure 100 uses an electric current passage through dual-semiconductor junction.

The thermal energy absorption during electron transition between materials is implemented to optimizes cooling efficiency. The top-loading portable temperature-controlled enclosure 100 can achieve target temperature (2° C.) within 2-hour initialization period. The top-loading portable temperature-controlled enclosure 100 implements temperature maintenance to maintain 2-8° C. range for 72 hours without external power.

An example Thermal Management System of the internal payload chamber incorporates a thermal management design. As seen below, the top-loading portable temperature-controlled enclosure 100 includes a chamber construction that includes payload 104. Here, the material composition can include a specialized heat-absorbing material combined with aluminum. The top-loading portable temperature-controlled enclosure 100 utilizes thermal spreading via an engineered aluminum structure for optimal temperature distribution. The top-loading portable temperature-controlled enclosure 100 performs heat absorption via a material matrix for thermal energy management.

The top-loading portable temperature-controlled enclosure 100 provides dynamic temperature control. Primary cooling is performed via a solid-state semiconductor chip (e.g. discussed infra). Supplementary cooling can be performed via a thermal mass buffer system. Hybrid operation between thermal mass and active cooling Response system can be used for temperature maintenance. Automated cooling bursts for temperature deviation compensation can be performed.

The top-loading portable temperature-controlled enclosure 100 can include a power and environmental adaptation power system 1102. The top-loading portable temperature-controlled enclosure 100 includes an input compatibility, by way of example of a Universal AC power (110V/220V) and an integrated charging system. Battery operation can be for 72-hour autonomous operation capability.

Optimized power consumption during steady-state operation can be obtained using bi-directional temperature control capability. For example, in a winter mode operation, the top-loading portable temperature-controlled enclosure 100 functions in extreme cold environments (−20° C. to −30° C.). Thermal management systems 1104 of the top-loading portable temperature-controlled enclosure 100 can maintains 2-8° C. in both hot and cold ambient conditions. An example environmental range enables The top-loading portable temperature-controlled enclosure 100 to be functional across extreme temperature variations.

The top-loading portable temperature-controlled enclosure 100 includes a monitoring and communication system 1106 for temperature monitoring. Real-time temperature tracking is implemented across continuous internal temperature measurement. The top-loading portable temperature-controlled enclosure 100 includes a digital display for current temperature indication. The top-loading portable temperature-controlled enclosure 100 includes an alert system for temperature deviations. The top-loading portable temperature-controlled enclosure 100 includes a communication infrastructure 1108 that can include an integrated LTE module with SIM card and/or GPS location tracking capability. The top-loading portable temperature-controlled enclosure 100 can perform data transmission intervals (e.g. at 4-5 minutes. The top-loading portable temperature-controlled enclosure 100 also includes cloud connectivity for remote monitoring. A backup SD card storage system can be included for offline data logging. The top-loading portable temperature-controlled enclosure 100 includes a Data Management module 1110 for continuous temperature logging and location tracking and recording. The top-loading portable temperature-controlled enclosure 100 can also perform automated cloud data synchronization.

The top-loading portable temperature-controlled enclosure 100 includes an Operation and Performance Temperature Performance module that manages an initial cooldown (e.g. 2 hours to reach target temperature with a temperature range: 2-8° C. maintenance and operation duration of 72 hours on battery power).

A thermal interface material utilizes a high thermal conductivity compound with controlled thickness application and full surface coverage verification. Mounting pressure can be maintained at 30-40 PSI through a spring-loaded mechanism, ensuring even pressure distribution across the chip surface and compensation for thermal expansion and contraction in some example embodiments.

The top-loading configuration represents a significant advancement in portable temperature-controlled storage, combining innovative solid-state cooling technology with thermal management and monitoring systems. The design achieves exceptional efficiency and reliability while maintaining precise temperature control across varied environmental conditions.

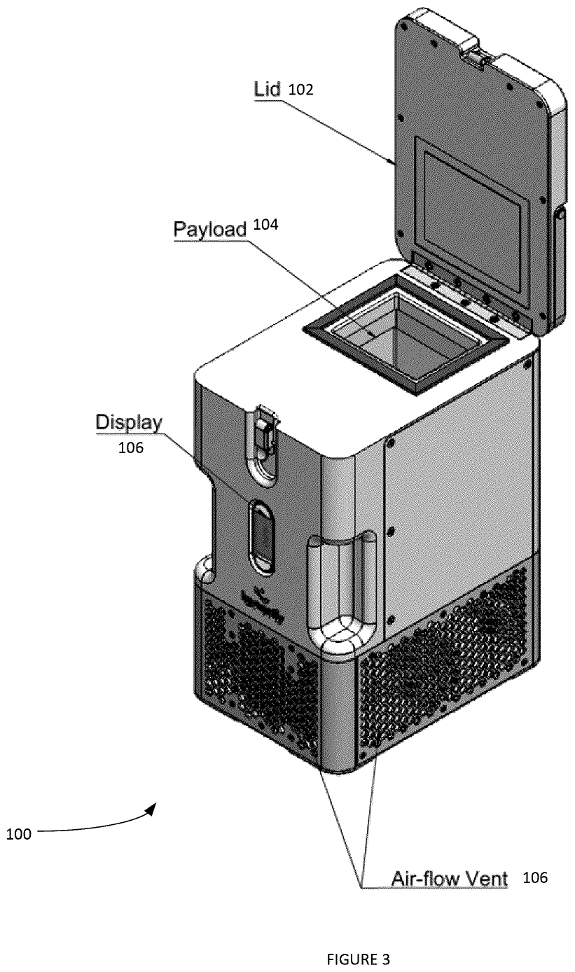

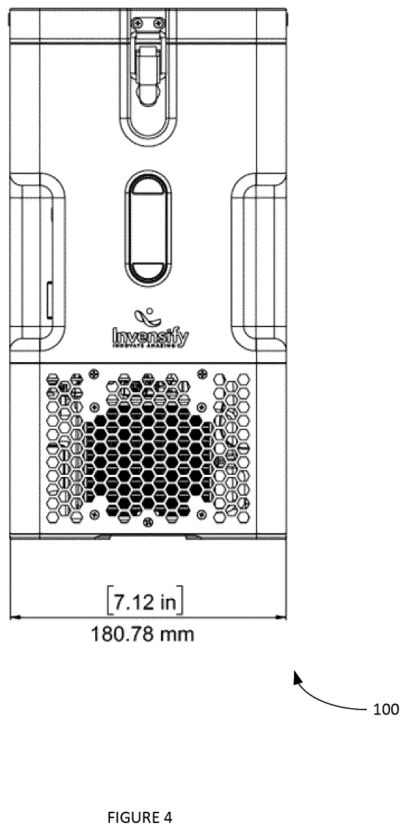

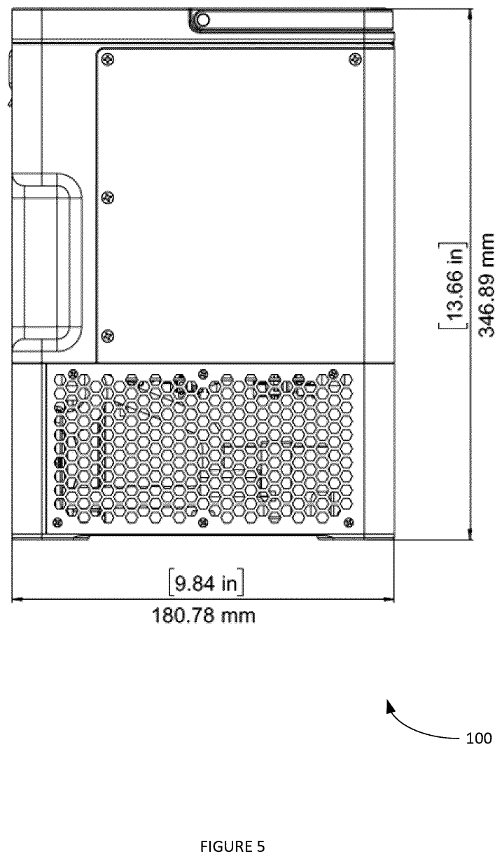

More specifically, FIG. 1 is a top view of example embodiment of a portable temperature-controlled enclosure 100, according to some embodiments. FIGS. 2 and 3 are isometric views of example embodiment of a portable temperature-controlled enclosure 100, according to some embodiments. FIG. 4 is a front view of example embodiment of a portable temperature-controlled enclosure 100, according to some embodiments. FIG. 5 is a side view of example embodiment of a portable temperature-controlled enclosure 100, according to some embodiments.

In one embodiments, portable temperature-controlled enclosure 100 can have a top-loading configuration with example payload dimensions: 3.2″×4.1″×5.5″. An example top opening capacity can be one (1) liter. Overall dimensions, by way of example, can be 107.78 mm×119.92 mm×166.84 mm. Portable temperature-controlled enclosure 100 provides a top access lid for payload (e.g. medications, etc.) insertion.

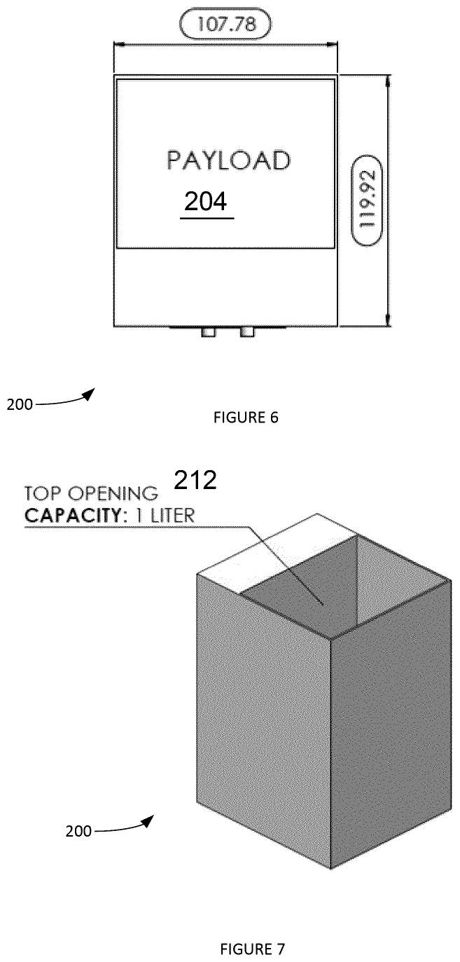

FIG. 6-9 illustrate various example views of an aluminum cooling chamber portable unit 200, according to some embodiments. Aluminum cooling chamber portable unit 200 can be the internal cooling/heating system of portable temperature-controlled enclosure 100.

Aluminum cooling chamber portable unit 200 of portable temperature-controlled enclosure 100 comprises a thermoelectric cooling mechanism wherein electrical power is transmitted through a strategically positioned semiconductor chip 202 mounted at a calculated angular orientation relative to the aluminum payload chamber 204. The semiconductor chip 202 incorporates a material combination wherein electrons traverse between different semiconductor elements, creating an energy absorption effect at the material junction interfaces. This energy absorption phenomenon, occurring at the precise locations where the material composition transitions, facilitates the cooling process through electron mobility differentials between the semiconductor materials.

The thermal management system utilizes direct thermal coupling between the semiconductor chip 202 and an aluminum payload chamber 204, whereby the energy absorption at the material junctions actively extracts heat from the payload area through the aluminum wall interface. The extracted thermal energy is subsequently transferred to a closed-loop cooling system 206 comprising fluid-carrying pipes 208 directly coupled to the posterior surface of the semiconductor chip (e.g. can include a heat sink system). The cooling loop 206 employs either water or antifreeze as the working fluid, circulating through an engineered pipe network via an integrated pump mechanism.

The system's thermal circuit can be completed through a fan-assisted heat exchanger configuration 214, wherein the heated working fluid from the cooling loop 206 is actively cooled before being recirculated through the system. The angular mounting of the semiconductor chip, deliberately oriented at a calculated angle rather than perpendicular to the payload chamber, achieves enhanced cooling distribution by optimizing the radius of coolness spread and increasing the effective surface area coverage. This angular configuration demonstrably improves the speed and uniformity of temperature distribution compared to traditional perpendicular mounting arrangements.

The thermal control system can operate in a dual-power configuration, initially utilizing wall power for the cooldown phase until the target temperature (typically 2° C.) is achieved, at which point the system transitions to battery power through a lithium polymer battery assembly capable of maintaining temperature control for 72 hours of autonomous operation. The internal configuration includes various top-loading variants (e.g. via top opening 212, etc.) while maintaining identical operational principles, with the semiconductor chip positioning optimized for each configuration to maximize cooling efficiency through enhanced radial distribution patterns.

The angular orientation of the semiconductor chip 202 relative to the payload chamber wall facilitates superior thermal spreading characteristics. The cooling effect disperses in a radial pattern rather than traditional linear distribution, resulting in more efficient coverage of the payload surface area and accelerated temperature equalization throughout the chamber. This geometric optimization of the semiconductor chip 202 placement enables the system to achieve more comprehensive thermal coverage compared to conventional perpendicular mounting configurations, as the angular positioning creates an expanded radius of cooling influence that enhances the overall heat absorption efficiency of the system.

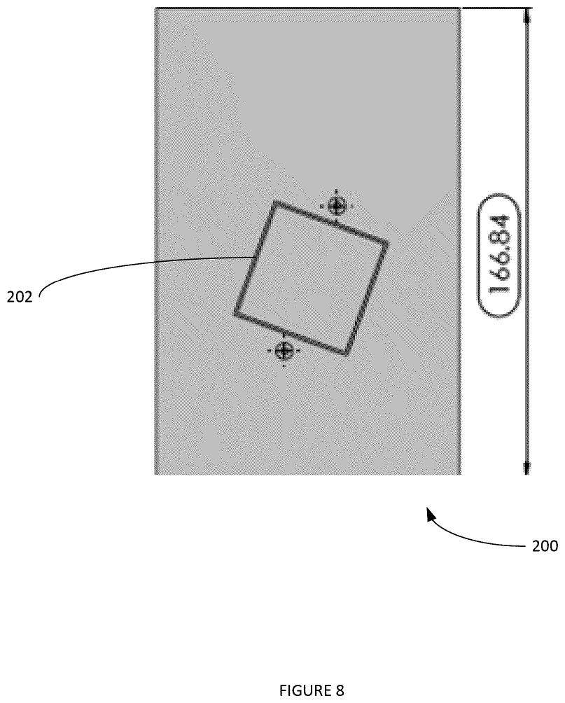

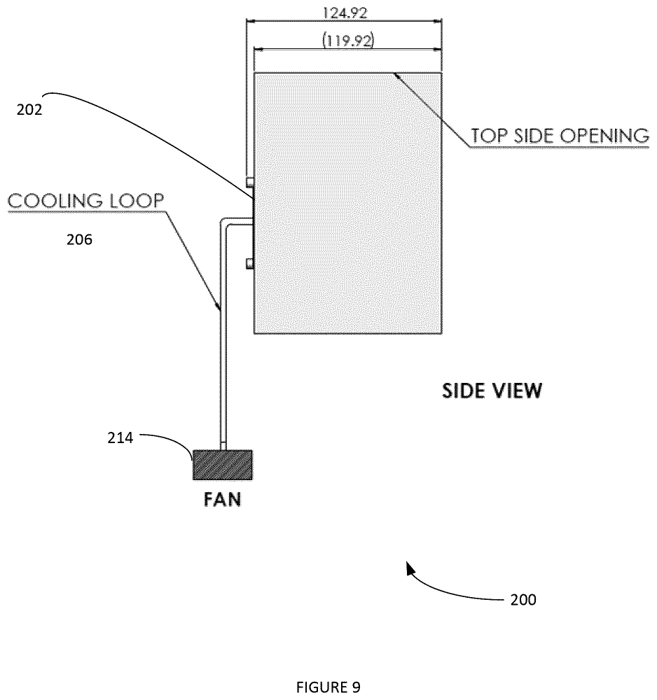

More specifically, FIG. 6 illustrates a top-view of aluminum cooling chamber portable unit 200, according to some embodiments. FIG. 7 illustrates a isometric-view of aluminum cooling chamber portable unit 200, according to some embodiments. FIG. 8 illustrates a rear-view of aluminum cooling chamber portable unit 200, according to some embodiments. FIG. 9 illustrates a side-view of aluminum cooling chamber portable unit 200, according to some embodiments.

### Example Computer Architecture and Systems

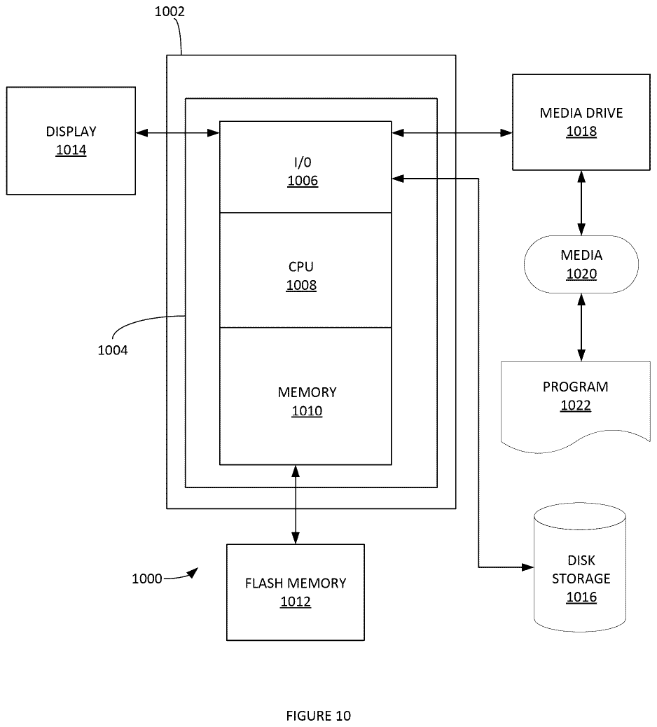

FIG. 10 depicts an exemplary computing system 1000 that can be configured to perform any one of the processes provided herein. In this context, computing system 1000 may include, for example, a processor, memory, storage, and I/O devices (e.g., monitor, keyboard, disk drive, Internet connection, etc.). However, computing system 1000 may include circuitry or other specialized hardware for carrying out some or all aspects of the processes. In some operational settings, computing system 1000 may be configured as a system that includes one or more units, each of which is configured to carry out some aspects of the processes either in software, hardware, or some combination thereof.

FIG. 10 depicts computing system 1000 with a number of components that may be used to perform any of the processes described herein. The main system 1002 includes a motherboard 1004 having an I/O section 1006, one or more central processing units (CPU) 1008, and a memory section 1010, which may have a flash memory card 1012 related to it. The I/O section 1006 can be connected to a display 1014, a keyboard and/or other user input (not shown), a disk storage unit 1016, and a media drive unit 1018. The media drive unit 1018 can read/write a computer-readable medium 1020, which can contain programs 1022 and/or data. Computing system 1000 can include a web browser. Moreover, it is noted that computing system 1000 can be configured to include additional systems in order to fulfill various functionalities. Computing system 1000 can communicate with other computing devices based on various computer communication protocols such a Wi-Fi, Bluetooth® (and/or other standards for exchanging data over short distances includes those using short-wavelength radio transmissions), USB, Ethernet, cellular, an ultrasonic local area communication protocol, etc.

Thermo-electric cooler pump can be managed by a computing system in the portable smart refrigerator. The computing system can be coupled with an exterior display. Exterior display can display various parameters (e.g. temperature, batter power, etc.) of the portable smart refrigerator. Computing system can also be coupled with various other systems such as, inter alia: temperature sensors, digital clocks, Wi-Fi systems, etc.

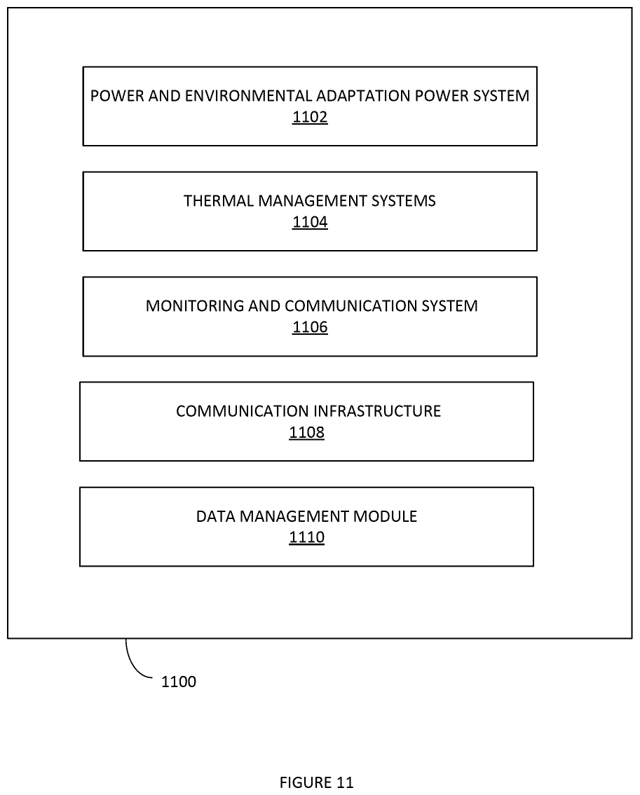

FIG. 11 illustrates a logical view 1100 of a portable temperature-controlled enclosure, according to some embodiments. Power and environmental adaptation power system 1102. The top-loading portable temperature-controlled enclosure 100 includes an input compatibility, by way of example of a Universal AC power (110V/220V) and an integrated charging system. Thermal management systems 1104 manage the temperature of top-loading portable temperature-controlled enclosure 100. Thermal management systems 110 of the top-loading portable temperature-controlled enclosure 100 can maintain 2-8° C. in both hot and cold ambient conditions. Monitoring and communication system 1106 for temperature monitoring. Real-time temperature tracking is implemented across continuous internal temperature measurement. The top-loading portable temperature-controlled enclosure 100 includes a digital display for current temperature indication. The top-loading portable temperature-controlled enclosure 100 includes an alert system for temperature deviations. The top-loading portable temperature-controlled enclosure 100 includes a communication infrastructure 1108 that can include an integrated LTE module with SIM card and/or GPS location tracking capability. The top-loading portable temperature-controlled enclosure 100 can perform data transmission intervals (e.g. at 4-5 minutes. The top-loading portable temperature-controlled enclosure 100 also includes cloud connectivity for remote monitoring. A backup SD card storage system can be included for offline data logging. The top-loading portable temperature-controlled enclosure 100 includes a Data Management module 1110 for continuous temperature logging and location tracking and recording.

Additional information on chip positioning is now discussed. The innovative cooling system centers around a precisely engineered 40 mm×40 mm semiconductor chip that represents a significant advancement in portable refrigeration technology. This chip, comprising multiple semiconductor junctions arranged in an optimized pattern, is mounted at a carefully calculated 20-degree angle relative to the payload chamber wall, deviating from traditional perpendicular mounting approaches. This specific angular orientation was chosen to maximize the cooling efficiency through enhanced radial distribution patterns.

The mounting configuration creates a thermal management system where the chip interfaces directly with the aluminum chamber wall for maximum thermal conductivity. This direct coupling is maintained by a spring-loaded mechanism that ensures a consistent 30-40 PSI mounting pressure, crucial for optimal heat transfer. The interface between the chip and wall utilizes a high thermal conductivity compound with carefully controlled thickness and verified full surface coverage.

The 20-degree mounting angle serves a critical purpose in the system's operation. Unlike conventional perpendicular mounting, which typically results in linear cooling distribution, this angular orientation creates an expanded radius of cooling influence. This radial distribution pattern enables more comprehensive coverage of the payload surface area and facilitates faster temperature equalization throughout the chamber. The result is a more efficient and effective cooling system that achieves superior thermal coverage compared to traditional mounting configurations.

In the top-loaded configuration, the chip is positioned lower, near the midsection of the wall, with the temperature sensor strategically placed inside the payload wall towards the bottom side. This positioning was specifically chosen to optimize the cooling effect in relation to the temperature sensor location. The entire setup demonstrates a carefully engineered approach to thermal management, where each component's position has been optimized for maximum efficiency.

The semiconductor chip's design and mounting create a cooling effect that disperses in a radial pattern rather than a traditional linear distribution. This radial dispersion is particularly effective because it provides more uniform coverage across the payload area. The angular mounting effectively increases the total area over which the cooling effect spreads, resulting in more efficient temperature control throughout the chamber. This innovative approach to chip mounting and cooling distribution represents a significant advancement in portable refrigeration technology, offering improved performance over conventional perpendicular mounting systems.

The system's overall design reflects a deep understanding of thermal dynamics and practical engineering considerations. By combining the precise 40 mm×40 mm chip dimensions with the 20-degree mounting angle and strategic positioning relative to temperature sensors, the system achieves optimal cooling performance while maintaining efficient use of space within the portable unit. The careful attention to mounting pressure, thermal compound application, and interface design ensures reliable and consistent performance, making this cooling system particularly well-suited for portable applications requiring precise temperature control.

### Aluminum Hydrocarbon Coated Pin Plate

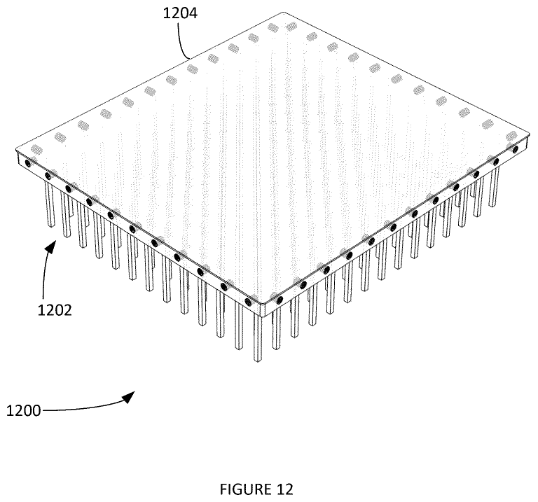

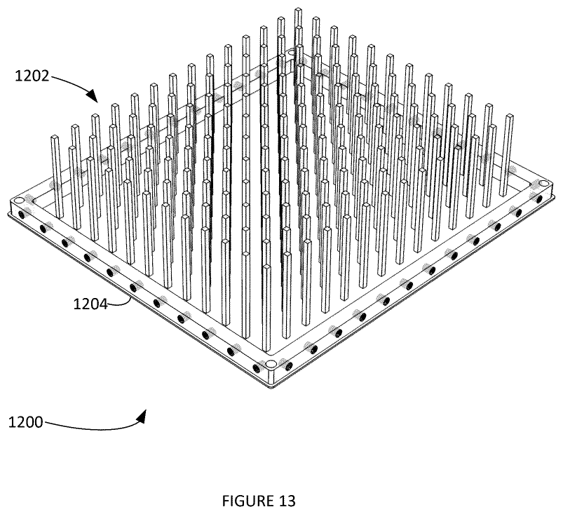

The aluminum hydrocarbon coated pin plate constitutes a thermally conductive interface structure configured for integration within an advanced cooling assembly. The component comprises an aluminum substrate on which a plurality of pins are formed, each pin coated with a hydrocarbon layer deposited through a controlled polymerization process. In one embodiment, the plate includes approximately one hundred and twenty pins arranged in a predetermined pattern to provide an extended surface area that increases conductive heat transfer and enhances overall thermal efficiency. It is noted that other pin configurations can be utilized as well in other embodiments. For example, a twelve by fourteen configuration is shown in FIGS. 12 and 13, which yields approximately one hundred and sixty eight pins depending on selected pitch and base plate dimensions.

The component is manufactured according to strict dimensional tolerances to ensure mechanical compatibility, consistent thermal conduction, and reliable assembly within a larger system. These tolerances include a hole diameter tolerance of plus or minus 0.025 millimeters, a hole position tolerance of plus or minus 0.05 millimeters, a wall thickness tolerance of plus or minus 0.05 millimeters, and an outer dimension tolerance of plus or minus 0.1 millimeters. Threaded features are formed with a metric thread diameter of five millimeters and a standard M5 by 0.8 thread pitch, enabling standardized fastening and stable mechanical coupling. Any prior reference to a 0.3175 millimeter thread pitch is a unit conversion error and is instead associated with pin pitch as described below. The adherence to these tolerances facilitates predictable heat transfer performance and ensures repeatable alignment with complementary structures.

The pin architecture includes pins each having a diameter of approximately five millimeters, arranged uniformly across the upper surface of the substrate. In representative embodiments, the pins are arranged at a center to center spacing of approximately 0.3175 inches, corresponding to about 8.07 millimeters between adjacent pins. The geometric layout of the pins forms a high density conductive array that promotes efficient heat dispersion. The selected pitch, height, and diameter of the pins are engineered to maintain a balanced thermal gradient across the plate, while the threaded features allow the plate to be incorporated into a variety of thermal management configurations using standard mechanical interfaces.

All exposed surfaces of the aluminum substrate, including the complex pin geometries, receive a hydrocarbon composite coating formed through a controlled thermal polymerization process. In representative embodiments, tetradecane is blended with a polymer material and subjected to elevated temperature for an extended period of time to form a wax like solid polymerized hydrocarbon composite. This composite material is applied to the aluminum structure and allowed to cure, forming a continuous thin solid coating across the curved pin surfaces and planar substrate surfaces. This coating is applied with uniform thickness and strong adhesion to enhance surface conductivity, reduce oxidation, and improve thermal stability under sustained thermal cycling. The coating preserves the natural finish of the aluminum while providing modified surface properties optimized for rapid heat transfer across the metal to coating boundary.

The pin plate is designed for direct thermal and mechanical coupling to a cooling chip or cooling module. In one embodiment, the thermoelectric semiconductor chip seats against a clean upper plate surface positioned above the pin array. This arrangement establishes a bidirectional thermal conduction pathway that enables cooling energy to propagate from the cooling module into the pin structure during cooling mode, while simultaneously allowing heat to be delivered back toward the cooling module during heating mode.

The pin geometry operates in cooperation with complementary conductive structures within the cooling chip to create a coupled thermal interface. The high surface area provided by the pin array supports rapid heat exchange, and the hydrocarbon coated surfaces reduce boundary resistance at the chip to plate contact region. The combination of these features improves the conduction efficiency between the cooling chip and the pin plate and increases the rate at which heat is dissipated into downstream thermal management stages.

The plate also functions as an intermediary conduction component within a multi stage cooling assembly. The aluminum material, polymerized hydrocarbon composite coating, and high density pin layout collectively support distributed thermal flow paths that reduce localized thermal concentrations. The design is tailored to complement the internal thermal architecture of the cooling chip, enabling harmonized thermal performance across components and improving the stability of the overall cooling system.

Fabrication of the pin plate requires precision machining and controlled surface treatment processes. The polymerized hydrocarbon composite coating must be applied under conditions that ensure continuous and uniform coverage, particularly across the narrow spaces and curved surfaces of the pin array. Variations in coating thickness, pin height, or machining tolerances can alter thermal interface resistance and mechanical compatibility. Therefore, process controls are maintained throughout manufacturing. These considerations enable consistent thermal performance, reliable long term adhesion of the coating, and predictable integration within the target cooling system architecture.

The aluminum hydrocarbon coated pin plate reflects an advancement in thermal management design by combining tightly controlled engineering tolerances, a high density pin geometry, and a specialized polymerized surface coating to form a highly efficient conductive interface for compact and high power electronic systems.

The aluminum hydrocarbon coated pin plate is incorporated into the portable temperature controlled enclosure as the primary heat rejection component positioned on the hot side of the thermoelectric semiconductor chip. Within the refrigerator cooling architecture, the thermoelectric semiconductor chip is mounted at a calculated angular orientation relative to the aluminum payload chamber wall so that its cold side directly absorbs heat from the payload chamber. The aluminum hydrocarbon coated pin plate is positioned in direct thermal contact with the hot side of the thermoelectric semiconductor chip, forming the initial conductive pathway for removing the thermal energy extracted from the payload chamber.

The upper surface of the pin plate provides a planar thermal interface region that mates with the thermoelectric semiconductor chip through a high conductivity thermal compound and a controlled mounting pressure maintained by mechanical fasteners using calibrated torque and spring washers. Heat entering the body of the pin plate is distributed through the aluminum substrate and into the array of hydrocarbon coated pins that extend downward into the lower cooling compartment of the enclosure. This lower compartment contains the airflow vents and the fan assisted heat exchanger. The pins are arranged so that their entire length is exposed to the moving air stream created by the fan. As the fan draws outside air through the ventilation openings on the enclosure exterior, air moves across and between the pins, removing heat from the coated aluminum structures through convection.

The hydrocarbon composite coating enhances heat transfer by improving surface conduction, reducing thermal boundary resistance, and preventing oxidation of the aluminum substrate. The uniformly applied polymerized coating maintains consistent performance throughout repeated thermal cycles. The large number of pins, their adjusted pitch, and their selected heights create substantial convective surface area, allowing heat to dissipate efficiently even during battery powered operation.

The pin plate is secured to internal structural supports using its metric threaded mounting features. These threaded features align with corresponding mounting points inside the cooling compartment, ensuring that the plate remains in precise position relative to the thermoelectric semiconductor chip and the fan driven airflow pathway. The dimensional tolerances of the plate, including hole placement tolerance, wall thickness tolerance, and outer dimension tolerance, ensure that the plate aligns consistently with the angularly mounted thermoelectric semiconductor chip and maintains the required thermal contact pressure.

When installed, the aluminum hydrocarbon coated pin plate establishes a continuous thermal pathway that extends from the payload chamber, through the thermoelectric semiconductor chip, into the pin plate, through the pin array, and into the forced air convection region located downstream of the heat exchanger. As the fluid based cooling loop and the fan remove thermal energy from the lower compartment, the pin plate stabilizes the temperature of the thermoelectric semiconductor chip and prevents thermal saturation. The rapid and uniform heat rejection provided by the coated pin array complements the radial cooling distribution produced by the angularly mounted thermoelectric semiconductor chip. This thermal integration enables the portable enclosure to maintain a target temperature range of approximately two degrees Celsius to approximately eight degrees Celsius for extended operational periods without external power.

By placing the aluminum hydrocarbon coated pin plate directly against the hot side of the thermoelectric semiconductor chip and positioning the pins within the active airflow corridor of the enclosure, the system achieves an efficient thermal management design that enhances heat spreading, reduces thermal resistance, and supports long duration autonomous temperature control in a compact portable refrigeration unit.

The aluminum hydrocarbon coated pin plate can be used in a range of angular mounting configurations in which a thermoelectric semiconductor chip is mounted at a calculated angle relative to a payload chamber wall. In some implementations the thermoelectric semiconductor chip is mounted at a non perpendicular angle so that heat flow enters the pin plate along an oblique thermal path rather than strictly normal to the plate surface. For example, the thermoelectric semiconductor chip can be mounted at about twenty degrees, about forty degrees, about forty five degrees, or at another calculated angle with respect to the interior surface of a hydrocarbon coated payload chamber such as a one liter chamber or a twelve liter chamber. These angular configurations are selected based on thermal calculations that shape how cooling propagates through the chamber volume, and the pin plate is configured to receive heat from the thermoelectric semiconductor chip under any of these orientations and to redistribute that heat through its multi pin geometry.

The hydrocarbon composite coating used on the pin plate can be the same class of material employed on other components of the cooling architecture, such as hydrocarbon coated payload chambers, fin plates, grills, or other aluminum interface structures. In some embodiments a hydrocarbon composite material formed from tetradecane and a polymer material is applied to the aluminum substrate through a thermal polymerization or co polymerization process, forming a continuous thermal network that extends across the payload chamber wall, the thermoelectric semiconductor chip interface surface, and the aluminum pin plate itself. In certain versions the aluminum substrate can also be anodized prior to coating, and in some cases the anodized surface can be sand blasted before the hydrocarbon composite layer is applied in order to increase effective surface roughness and thereby enhance thermal conduction.

The aluminum hydrocarbon coated pin plate can be integrated into multiple cooling chamber geometries and insulation schemes. The thermal interface structure can be used with rectangular, cubic, pyramidal, cylindrical, or other mechanically engineered chamber shapes, including ribbed, pocketed, windowed, or weight reducing geometries. The pin plate and associated hydrocarbon coated aluminum structures can be embedded within or coupled to payload chambers that are surrounded by different insulating plastics such as ABS, generic polymer, co polymer, or homopolymer materials, and can also be used in compact palm sized cooling units or in larger payload volumes such as twelve liter or forty two liter enclosures.

Within the overall thermal stack, the pin plate can be positioned in several different relative orientations while maintaining functional compatibility with the cooling architecture. In one representative configuration the stack comprises a hydrocarbon coated payload chamber or plate, a thermoelectric semiconductor chip coupled to that chamber, the aluminum hydrocarbon coated pin plate on the hot side of the chip, a cooling block coupled to the pin plate, and a pump driven cooling loop and fan assisted heat exchanger that remove heat from the block and from air flowing around the pins. In other implementations the pin plate can be placed above the thermoelectric semiconductor chip, below the thermoelectric semiconductor chip, or laterally adjacent to the thermoelectric semiconductor chip, provided that a thermally conductive interface is maintained.

The present invention also contemplates the relationship between fins and pins as alternative mechanisms for increasing surface area within a compact volume. Prior designs employ aluminum and or copper fin plates and cooling blocks that incorporate large numbers of thin fins to expand surface area in contact with coolant or air. The aluminum hydrocarbon coated pin plate applies the same surface area principle using pins rather than fins, where the pins function as compact high density surface features that provide elongated conduction paths in a limited footprint.

The thermoelectric semiconductor chip operates as the bidirectional thermal pumping element within the cooling architecture and includes a cold side and a hot side that develop a controlled temperature differential under electrical drive. The cold side of the thermoelectric semiconductor chip is positioned in direct thermal communication with the hydrocarbon coated payload chamber wall so that the cold side absorbs heat from the payload compartment.

The aluminum hydrocarbon coated pin plate described herein is positioned on the hot side of the thermoelectric semiconductor chip and functions as the primary heat rejection component that receives the thermal energy pumped through the thermoelectric semiconductor chip from the payload chamber.

The upper surface of the aluminum hydrocarbon coated pin plate forms a planar thermal interface region that mates with the hot side of the thermoelectric semiconductor chip through a high conductivity thermal interface compound. The dimensional tolerances of the aluminum hydrocarbon coated pin plate are selected so that the plate aligns with the thermoelectric semiconductor chip under the required mounting pressure while maintaining full surface contact across the thermal interface region.

Thermal energy that enters the aluminum hydrocarbon coated pin plate is transported into the array of hydrocarbon coated pins that extend away from the thermoelectric semiconductor chip and into the downstream heat rejection region.

The thermoelectric semiconductor chip can be mounted at a calculated angle relative to the hydrocarbon coated payload chamber wall, and under such conditions the aluminum hydrocarbon coated pin plate receives heat along an oblique thermal path.

The aluminum hydrocarbon coated pin plate establishes the initial thermal spreading and heat rejection stage on the hot side of the thermoelectric semiconductor chip.

FIG. 12 illustrates an aluminum hydrocarbon coated pin plate assembly according to some embodiments.

The base plate serves as the mechanical and thermal coupling element that interfaces directly with the hot side of the thermoelectric semiconductor chip.

In one representative embodiment the assembly includes approximately one hundred and twenty pins, each having a diameter of about five millimeters and a center to center spacing of approximately 8.07 millimeters.

FIG. 13 illustrates the aluminum hydrocarbon coated pin plate assembly in another representative orientation.

Heat entering the base plate from the hot side of the thermoelectric semiconductor chip is distributed laterally across the aluminum substrate and then downward into the pins.

The pin plate assembly functions as a specialized hot side heat rejection structure within a multi stage thermal management stack.

In one example embodiment the pin plate assembly is machined from an aluminum substrate and subsequently coated with a hydrocarbon composite material applied through a controlled thermal polymerization process in which tetradecane is blended with a polymer material and heat treated to form a wax like solid coating. The assembly maintains a natural aluminum color and natural surface finish after coating. The pin plate assembly is manufactured to strict dimensional tolerances including a hole diameter tolerance of plus or minus 0.025 millimeters, a hole position tolerance of plus or minus 0.05 millimeters, a wall thickness tolerance of plus or minus 0.05 millimeters, and an outer dimension tolerance of plus or minus 0.1 millimeters. The pin plate assembly further includes metric threaded mounting features formed as standard M5 by 0.8 threaded holes. These tolerances and thread specifications support precise mechanical alignment within the cooling architecture, ensure stable attachment to internal structural supports, and maintain consistent thermal contact pressure between the base plate and the hot side of the thermoelectric semiconductor chip. The natural finish and uniform hydrocarbon composite coating preserve the thermal conductivity of the aluminum substrate while providing corrosion resistance, surface stability, and consistent thermal performance across repeated thermal cycles.

The aluminum hydrocarbon coated pin plate assembly comprises an aluminum base plate on which a plurality of pins are formed as an integral unitary structure. The pins extend from a lower face of the base plate into a downstream heat rejection region and are arranged in a regular rectangular grid pattern defined by an N by M array. In representative implementations the pin array may be arranged at a center-to-center spacing of approximately 0.3175 inches, corresponding to about 8.07 millimeters between adjacent pins. Although a regular rectangular grid is illustrated in certain embodiments, alternative arrangements including hexagonal packing or application-optimized irregular patterns may also be employed to improve localized heat transfer based on thermal load distribution.

The total number of pins is not fixed and may vary according to the dimensions of the base plate and the selected pin pitch. In one representative embodiment, the pin array comprises approximately 120 pins formed in a 10 by 12 arrangement at an 8.07 millimeter pitch. In other embodiments, a 12 by 14 arrangement may be employed to produce approximately 168 pins. The pin count may be increased or decreased based on payload volume, heat flux requirements, available airflow, and enclosure geometry.

Each pin extends from the lower surface of the base plate to a nominal height selected to optimize convective heat transfer. In representative embodiments, the pins extend to a height in the range of approximately 30 millimeters to approximately 50 millimeters. The pins may be manufactured with uniform height across the array or with variable heights across different regions of the base plate depending on local thermal performance requirements.

The aluminum base plate has outer dimensions selected according to payload size and system-level thermal requirements. In representative embodiments, the length and width of the base plate may fall within a range of approximately 200 millimeters to approximately 400 millimeters. The base plate thickness is selected to provide sufficient rigidity and conductive mass and may fall within a representative range of approximately 3 millimeters to approximately 12 millimeters. These dimensions may be scaled upward or downward depending on enclosure volume, structural mounting requirements, and expected thermal loads.

Mounting features formed in the aluminum base plate are tapped for standard metric fasteners. In representative embodiments the mounting holes are formed as standard M 5 by 0.8 threaded features. Any prior reference to a 0.3175 millimeter thread pitch is to be understood as a unit conversion error and properly refers instead to the pin pitch expressed in inches. The threaded mounting features are used in combination with mechanical fasteners, calibrated torque values, and spring washers to maintain uniform contact pressure between the base plate and a thermoelectric semiconductor device mounted on the base plate surface.

The hydrocarbon coating applied to the aluminum base plate and the plurality of pins is formed by blending tetradecane with a polymer material and heating the mixture at elevated temperature for an extended period of time to form a polymerized wax-like hydrocarbon composite. During this process, polymer chains form within the tetradecane material, converting the initially liquid hydrocarbon into a thin solid coating material. This coating material is then poured or deposited onto the aluminum pin structure and allowed to cure and solidify, resulting in a continuous thin layer of polymerized tetradecane composite that conforms to both curved pin surfaces and planar substrate surfaces. This composite coating provides enhanced surface conduction, corrosion resistance, oxidation inhibition, and long-term stability during repeated thermal cycling. In some embodiments, the same hydrocarbon composite coating is used on the payload chamber walls, thereby forming a chemically continuous thermal conduction network across multiple components of the cooling architecture.

The thermoelectric semiconductor device is mounted directly to the upper surface of the aluminum base plate to form a low thermal resistance interface between the two components. A high-conductivity thermal compound is disposed between the thermoelectric semiconductor device and the aluminum base plate to reduce thermal boundary resistance. Mechanical fasteners extending through the threaded mounting features apply controlled clamping force to maintain uniform contact pressure across the thermal interface. The plurality of pins extend downward from the opposite side of the base plate away from the thermoelectric semiconductor device and into an airflow corridor or ambient heat rejection region so that the pin array functions as the primary convective heat exchange surface.

The aluminum hydrocarbon coated pin plate provides bidirectional thermal conduction during system operation. Thermal energy entering the base plate from the hot side of the thermoelectric semiconductor device is spread laterally across the aluminum substrate and conducted axially along the plurality of pins into an airflow-driven or liquid-cooled heat rejection region during cooling mode. During heating mode, when current polarity is reversed within the thermoelectric semiconductor device, ambient thermal energy may be conducted from the pin array into the base plate and delivered to the thermoelectric semiconductor device. The pin plate thus supports both lateral thermal spreading across the base plate and axial heat transfer through the pins and functions as a bidirectional heat sink or heat source depending on operating mode.

The base plate may be mounted to the thermoelectric semiconductor device at a perpendicular orientation or at a calculated non perpendicular angle relative to a cooled payload chamber wall. When mounted at a non perpendicular angle, thermal energy enters the aluminum base plate along an oblique heat flow path rather than strictly normal to the plate surface. The aluminum hydrocarbon coated pin plate redistributes the incoming thermal energy laterally across the base plate and axially along the pins regardless of the incoming angle, thereby maintaining stable thermal performance under angular mounting configurations.

The pins extend into the active airflow corridor of the enclosure such that moving air passes between adjacent pins and across their hydrocarbon coated surfaces. This interaction creates a high-density convective interface that accelerates heat rejection even under low fan power conditions during battery powered operation. The combination of high surface area pin geometry, polymerized hydrocarbon composite coating, controlled mechanical clamping pressure, and precision machined aluminum substrate produces a highly efficient thermal interface structure for use on either side of a thermoelectric semiconductor device in portable temperature-controlled enclosures.

### Conclusion

Although the present embodiments have been described with reference to specific example embodiments, various modifications and changes can be made to these embodiments without departing from the broader spirit and scope of the various embodiments. For example, the various devices, modules, etc. described herein can be enabled and operated using hardware circuitry, firmware, software or any combination of hardware, firmware, and software (e.g., embodied in a machine-readable medium).

In addition, it can be appreciated that the various operations, processes, and methods disclosed herein can be embodied in a machine-readable medium and/or a machine accessible medium compatible with a data processing system (e.g., a computer system), and can be performed in any order (e.g., including using means for achieving the various operations). Accordingly, the specification and drawings are to be regarded in an illustrative rather than a restrictive sense. In some embodiments, the machine-readable medium can be a non-transitory form of machine-readable medium.

What is claimed by United States Patent:

1. A thermally conductive interface structure comprising: an aluminum substrate, a plurality of pins formed on the aluminum substrate, and a hydrocarbon coating applied to the aluminum substrate and to the plurality of pins, wherein the hydrocarbon coating is deposited through a controlled polymerization process, and wherein the plurality of pins are arranged in a predetermined pattern on the aluminum substrate to increase conductive heat transfer.

2. The thermally conductive interface structure of claim 1, wherein the plurality of pins comprises approximately one hundred and twenty pins.

3. The thermally conductive interface structure of claim 2, wherein each pin of the plurality of pins has a diameter of approximately five millimeters.

4. The thermally conductive interface structure of claim 3, wherein the aluminum substrate is manufactured with a hole diameter tolerance of plus or minus zero point zero two five millimeters, a hole position tolerance of plus or minus zero point zero five millimeters, a wall thickness tolerance of plus or minus zero point zero five millimeters, and an outer dimension tolerance of plus or minus zero point one millimeters.

5. The thermally conductive interface structure of claim 4, wherein the aluminum substrate comprises a metric threaded mounting feature having a thread diameter of five millimeters and a thread pitch of zero point eight millimeters.

6. The thermally conductive interface structure of claim 5, wherein the hydrocarbon coating forms a uniform layer across curved surfaces of the plurality of pins and planar surfaces of the aluminum substrate.

7. The thermally conductive interface structure of claim 6, wherein the hydrocarbon coating enhances thermal conduction, reduces oxidation of the aluminum substrate, and maintains thermal stability during repeated thermal cycling.

8. The thermally conductive interface structure of claim 7, wherein the aluminum substrate comprises a planar thermal interface region configured for thermal coupling to a thermoelectric semiconductor device.

9. The thermally conductive interface structure of claim 8, wherein the predetermined pattern of the plurality of pins forms a high density conductive array configured to distribute heat across the aluminum substrate and through the plurality of pins during operation.

10. The thermally conductive interface structure of claim 9, wherein the aluminum substrate and the plurality of pins collectively define a convective heat rejection surface configured to operate within a forced air cooling region.

11. A thermally conductive interface structure comprising:
an aluminum substrate,
a plurality of pins formed integrally with the aluminum substrate, and a
hydrocarbon coating disposed on the aluminum substrate and on the plurality of pins,
wherein the hydrocarbon coating is deposited through a controlled polymerization process to produce a continuous conductive layer that conforms to curved pin surfaces and planar substrate surfaces,
wherein the plurality of pins are arranged in a predetermined pattern on the aluminum substrate to define a high surface area conductive array, and
wherein the aluminum substrate and the plurality of pins are configured to receive thermal energy from a thermoelectric semiconductor device along an oblique heat flow path established by a non-perpendicular mounting orientation of the thermoelectric semiconductor device relative to a cooled payload chamber, and to redistribute the received thermal energy laterally across the aluminum substrate and axially along the plurality of pins to enhance thermal spreading and increase heat rejection efficiency.

12. The thermally conductive interface structure of claim 11, wherein the aluminum substrate is positioned on a hot side of a thermal pumping device that transfers thermal energy from a cooled payload chamber into the aluminum substrate for redistribution through the plurality of pins.

13. The thermally conductive interface structure of claim 12, wherein the cooled payload chamber comprises a hydrocarbon coated chamber wall forming a cold side thermal interface region configured to deliver heat into the thermal pumping device during operation.

14. The thermally conductive interface structure of claim 13, wherein the thermal pumping device is mounted between the hydrocarbon coated chamber wall and the aluminum substrate such that the aluminum substrate receives thermal energy propagated through the thermal pumping device and directs the received thermal energy across the aluminum substrate and along the plurality of pins.

15. A thermally managed refrigeration interface system comprising: an aluminum payload chamber defining an interior cooled volume and comprising a hydrocarbon coated chamber wall forming a cold side thermal interface region; a thermoelectric semiconductor device mounted adjacent to the hydrocarbon coated chamber wall such that a cold side of the thermoelectric semiconductor device is in direct thermal communication with the hydrocarbon coated chamber wall and a hot side of the thermoelectric semiconductor device is oriented away from the payload chamber; an aluminum pin plate assembly positioned in direct thermal contact with the hot side of the thermoelectric semiconductor device, the aluminum pin plate assembly comprising an aluminum base plate and a plurality of pins formed integrally with the aluminum base plate, each pin extending into a downstream heat rejection region; a hydrocarbon composite coating disposed on the aluminum base plate and on the plurality of pins, the hydrocarbon composite coating being formed by thermally polymerizing a blended mixture of tetradecane and a polymer material to produce a wax like solid coating that continuously conforms to curved pin surfaces and planar base plate surfaces; wherein the plurality of pins are arranged in a predetermined high density array comprising approximately one hundred and twenty pins arranged at a center to center pitch of approximately 8.07 millimeters with each pin having a diameter of approximately five millimeters and a nominal height in a range from approximately thirty millimeters to approximately fifty millimeters; wherein the aluminum base plate is manufactured with a hole diameter tolerance of plus or minus 0.025 millimeters, a hole position tolerance of plus or minus 0.05 millimeters, a wall thickness tolerance of plus or minus 0.05 millimeters, and an outer dimension tolerance of plus or minus 0.1 millimeters, and further comprises standard M5 by 0.8 threaded mounting features configured to maintain controlled contact pressure against the hot side of the thermoelectric semiconductor device using mechanical fasteners; wherein the thermoelectric semiconductor device is mounted at a non perpendicular angle relative to the hydrocarbon coated chamber wall such that thermal energy enters the aluminum base plate of the aluminum pin plate assembly along an oblique heat flow path; and wherein thermal energy propagated from the payload chamber through the thermoelectric semiconductor device is redistributed laterally across the aluminum base plate and axially along the plurality of pins into a forced air or liquid cooled heat rejection region, thereby establishing bidirectional thermal conduction capability for operation in both cooling and heating modes while preventing thermal saturation of the thermoelectric semiconductor device during extended autonomous operation.

16. The thermally managed refrigeration interface system of claim 15, wherein the predetermined high density array of the plurality of pins is arranged in a rectangular N by M grid pattern or in a hexagonal packing arrangement selected to improve localized heat transfer uniformity across regions of higher thermal flux on the aluminum base plate.

17. The thermally managed refrigeration interface system of claim 15, wherein the aluminum base plate is anodized prior to application of the hydrocarbon composite coating, and wherein the anodized surface is sand blasted before coating to increase effective surface roughness and enhance interfacial thermal conduction between the thermoelectric semiconductor device and the aluminum base plate.

18. The thermally managed refrigeration interface system of claim 15, wherein the forced air heat rejection region is configured to operate within a Reynolds number regime selected to maintain turbulent airflow between adjacent pins of the plurality of pins to maximize convective heat transfer during battery powered operation.

19. The thermally managed refrigeration interface system of claim 15, wherein the aluminum pin plate assembly is configured to operate under a duty cycled electrical power constraint imposed by a battery system, and wherein the plurality of pins and the hydrocarbon composite coating cooperatively maintain thermal stability of the thermoelectric semiconductor device during intermittent fan operation.

20. The thermally managed refrigeration interface system of claim 15, wherein the aluminum pin plate assembly is further configured to accommodate variable pin counts selected from approximately one hundred and twenty pins, approximately one hundred and sixty eight pins, or another array size determined by payload chamber geometry and thermal load requirements while maintaining the center to center pitch of approximately 8.07 millimeters.
